(19) United States
(12) Patent Application Publication
(10) Pub. No.: US 2005/0069819 A1
(43) Pub. Date: Mar. 31, 2005

(54) Method for forming resist pattern and method for manufacturing semiconductor device

(76) Inventor: Eishi Shiobara, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/951,894

(22) Filed: Sep. 29, 2004

(30) Foreign Application Priority Data
Sep. 30, 2003 (JP) 2003-340590

(51) Int. Cl. G03F 7/00

(52) U.S. Cl. 430/327; 430/322; 430/935

(57) ABSTRACT

According to an aspect of the invention, there is provided a method for forming a resist pattern by using a liquid immersion type exposing apparatus which executes exposure in a state in which a space between a resist film and an objective lens is filled with a liquid comprises forming a film to be processed on a substrate to be processed, forming the resist film on the substrate to be processed on which the film to be processed is formed, forming a resist protective film on the resist film and exposing the resist film after the formation of the resist protective film.

### CROSS-REFERENCE TO RELATED APPLICATIONS

This application is based upon and claims the benefit of priority from prior Japanese Patent Application No. 2003-340590, filed Sep. 30, 2003, the entire contents of which are incorporated herein by reference.

### BACKGROUND OF THE INVENTION

1. Field of the Invention

The present invention relates to a method for forming a resist pattern used in a lithography process of semiconductor device manufacturing, and a method for manufacturing a semiconductor device.

2. Description of the Related Art

A wavelength of light used in an exposing apparatus has become short according to miniaturization of a semiconductor device circuit. Meanwhile, to increase resolution of the exposing apparatus, suggestion has been made to use a liquid immersion type exposing apparatus which fills a space between an objective lens and a resist film with a liquid of a high refractive index. Accordingly, NA can be substantially increased, and a finer pattern can be formed. In the case of an ArF excimer laser exposing apparatus, use of water as the liquid has been suggested. An immersion technology of such a kind is described in “Nikkei Microdevices” by Nikkei BP Corporation, September edition (pp. 61 to 70).

However, when the liquid immersion type exposing apparatus is used, the liquid contacts the resist film directly. Therefore, for example, if a chemically amplified positive resist is used, the acid generated in the resist flows into the liquid, thereby the acid on the surface of the resist film decrease. In this case, the resist film may fail to have a desired shape.

Furthermore, when the liquid immersion type exposing apparatus is used, generation of bubbles in the liquid between the resist film and the lens may deteriorate an image quality. Especially, since a surface of the resist film is generally hydrophobic, bubbles are easily generated in an interface between the resist film and the liquid.

### BRIEF SUMMARY OF THE INVENTION

According to an aspect of the invention, there is provided a method for forming a resist pattern by using a liquid immersion type exposing apparatus which executes exposure in a state in which a space between a resist film and an objective lens is filled with a liquid, comprising: forming a film to be processed on a substrate to be processed; forming the resist film on the substrate to be processed on which the film to be processed is formed; forming a resist protective film on the resist film; and exposing the resist film after the formation of the resist protective film.

According to another aspect of the invention, there is provided a method for forming a resist pattern by using a liquid immersion type exposing apparatus which executes exposure in a state in which a space between a resist film and an objective lens is filled with a liquid, comprising: forming a film to be processed on a processed substrate; forming the resist film on the substrate to be processed on which the film to be processed is formed; making hydrophilic a surface of the resist film with which the liquid is brought into contact; and exposing the resist film after the surface thereof is made hydrophilic.

According to another aspect of the invention, there is provided a method for forming a resist pattern by using a liquid immersion type exposing apparatus which executes exposure in a state in which a space between a resist film and an objective lens is filled with a liquid, comprising: forming a film to be processed on a substrate to be processed; forming the resist film on the substrate to be processed on which the film to be processed is formed; forming a resist protective film on the resist film; making hydrophilic a surface of the resist protective film with which the liquid is brought into contact; and exposing the resist film after the surface of the resist protective film is made hydrophilic.

According to another aspect of the invention, there is provided a method for manufacturing a semiconductor device by using a liquid immersion type exposing apparatus which executes exposure in a state in which a space between a resist film and an objective lens is filled with a liquid, comprising: forming a film to be processed on a semiconductor substrate; forming the resist film on the semiconductor substrate on which the film to be processed is formed; forming a resist protective film which becomes insoluble in the liquid on the resist film; and exposing the resist film after the formation of the resist protective film.

According to another aspect of the invention, there is provided a method for manufacturing a semiconductor device by using a liquid immersion type exposing apparatus which executes exposure in a state in which a space between a resist film and an objective lens is filled with a liquid, comprising: forming a film to be processed on a semiconductor substrate; forming the resist film on the semiconductor substrate on which the film to be processed is formed; making hydrophilic a surface of the resist film with which the liquid is brought into contact; and exposing the resist film after the surface thereof is made hydrophilic.

According to another aspect of the invention, there is provided a method for manufacturing a semiconductor device by using a liquid immersion type exposing apparatus which executes exposure in a state in which a space between a resist film and an objective lens is filled with a liquid, comprising: forming a film to be processed on a semiconductor substrate; forming the resist film on the semiconductor substrate on which the film to be processed is formed; forming a resist protective film on the resist film; making hydrophilic a surface of the resist protective film with which the liquid is brought into contact; and exposing the resist film after the surface of the resist protective film is made hydrophilic.

### BRIEF DESCRIPTION OF THE SEVERAL VIEWS OF THE DRAWING

FIG. 1 is a view showing an apparatus configuration in which a method for forming a resist pattern according to a first embodiment is implemented;

FIGS. 2A to 2D are views showing a process flow of the method for forming the resist pattern according to the first embodiment;

FIGS. 3A to 3D are views showing the process flow of the method for forming the resist pattern according to the first embodiment;

FIGS. 4A and 4B are views showing resist pattern shapes of the first embodiment and a conventional example;

FIG. 5 is a view showing an apparatus configuration in which a method for forming a resist pattern according to a second embodiment is implemented;

FIGS. 6A to 6D are views showing a process flow of the method for forming the resist pattern according to the second embodiment;

FIGS. 7A to 7C are views showing the process flow of the method for forming the resist pattern according to the second embodiment;

FIGS. 8A to 8D are views showing a process flow of a method for forming a resist pattern according to a third embodiment;

FIGS. 9A to 9C are views showing the process flow of the method for forming the resist pattern according to the third embodiment;

FIGS. 10A to 10D are views showing a process flow of a method for forming a resist pattern according to a fourth embodiment;

FIGS. 11A to 11C are views showing the process flow of the method for forming the resist pattern according to the fourth embodiment;

FIGS. 12A to 12D are views showing a process flow of a method for forming a resist pattern according to a fifth embodiment;

FIGS. 13A to 13E are views showing the process flow of the method for forming the resist pattern according to the fifth embodiment;

FIGS. 14A to 14D are views showing a process flow of a method for forming a resist pattern according to a sixth embodiment;

FIGS. 15A to 15E are views showing the process flow of the method for forming the resist pattern according to the sixth embodiment;

FIGS. 16A to 16D are views showing a process flow of a method for forming a resist pattern according to a seventh embodiment; and

FIGS. 17A to 17E are views showing the process flow of the method for forming the resist pattern according to the seventh embodiment.

### DETAILED DESCRIPTION OF THE INVENTION

Next, the embodiments of the present invention will be described with reference to the accompanying drawings.

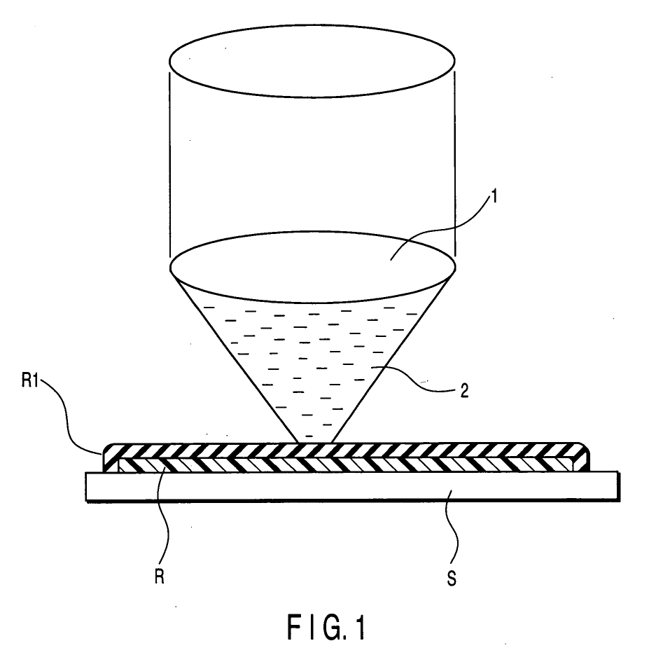

FIG. 1 is a view showing an apparatus configuration in which a method for forming a resist pattern according to a first embodiment is implemented. As shown in FIG. 1, a silicon substrate (semiconductor substrate, semiconductor wafer, substrate to be processed) S is arranged below an objective lens 1 disposed in a liquid immersion type exposing apparatus. A space between the objective lens 1 and the silicon substrate S is filled with a liquid (pure water) 2. As described later, a resist film R is formed on the silicon substrate S, and a resist protective film R1 is further formed on a surface of the resist film R.

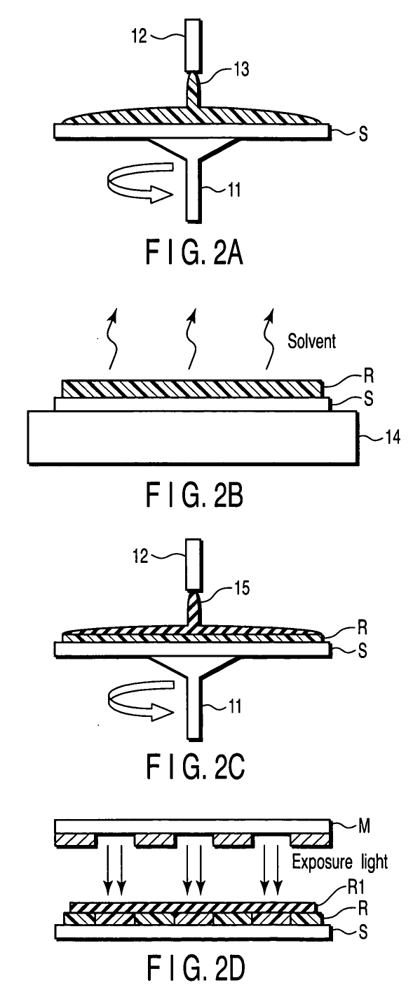

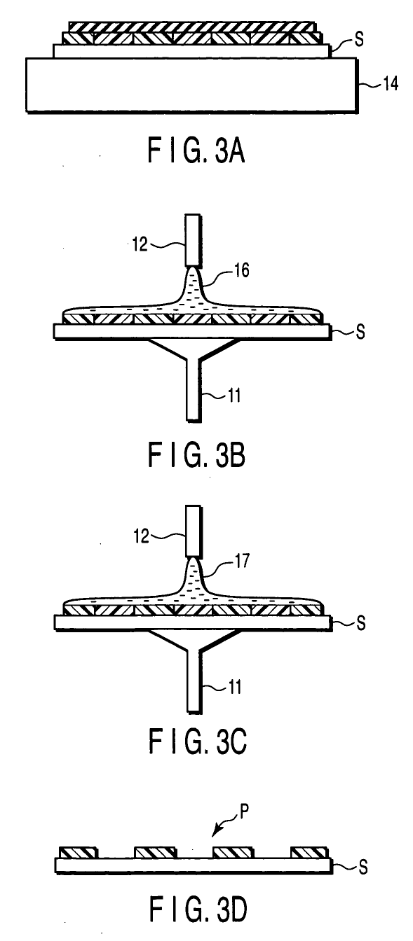

FIGS. 2A to 2D and FIGS. 3A to 3D are views showing a process flow of the method for forming the resist pattern according to the first embodiment. Hereinafter, the process of the resist pattern formation will be described with reference to FIGS. 2A to 2D and FIGS. 3A to 3D.

First, a reflection preventing film solution (ARC29A by Nissan Chemical Co. Ltd.) is applied on the silicon substrate S, baked on a hot plate at 190° C. for 60 sec., and a reflection preventing film (film to be processed) of a thickness of 80 nm is obtained.

Subsequently, as shown in FIG. 2A, a lower layer resist solution 13 is supplied through a nozzle 12 to the silicon substrate S while the silicon substrate S is rotated by a spin chuck 11. Accordingly, a methacrylate ArF chemical amplification type positive resist (film thickness of 300 nm) is applied on the reflection preventing film. Next, as shown in FIG. 2B, the silicon substrate S is baked on the hot plate 14 at 120° C. for 60 sec., and a resist film R is formed on the silicon substrate S.

Then, as shown in FIG. 2C, a protective film aqueous solution 15 is supplied through the nozzle 12 to the resist film R of the silicon substrate S while the silicon substrate S is rotated by the spin chuck 11. Accordingly, a polysilsesquioxane aqueous solution of a solid portion concentration 6 wt % is applied with a film thickness of 60 nm on the resist film R. Subsequently, heating treatment is executed on the hot plate of 120° C. for 60 sec., and insoluble treatment is carried out. Thus, a resist protective film R1 that becomes insoluble in the liquid 2 is formed on a surface of the resist film R.

Next, as shown in FIG. 2D, in a liquid immersion type ArF excimer laser exposing apparatus that uses water as a medium, a line-and-space pattern of a line width 100 nm is transferred through the objective lens 1 to the silicon substrate S by using a half-tone mask M of a transmittance 6% under conditions of NA=0.68, σ=0.75, and 2/3 orbicular zone illumination. Then, as shown in FIG. 3A, PEB treatment is executed on the hot plate 14 of 120° C. for 60 sec.

Next, as shown in FIG. 3B, a peeling liquid 16 is supplied through the nozzle 12 to the silicon substrate S. Accordingly, the silicon substrate S is immersed in a 0.1% hydrofluoric acid solution for 30 sec., and the polysilsesquioxane film, i.e., the resist protective film R1, is removed. Subsequently, as shown in FIG. 3C, a developing liquid 17 is supplied through the nozzle 12 to the silicon substrate S. Thus, the silicon substrate S is immersed in the developing liquid which contains a 2.38 wt % TMAH aqueous solution for 30 sec., and developing is carried out.

As a result, as shown in FIG. 3D, a resist pattern P of a good shape is obtained.

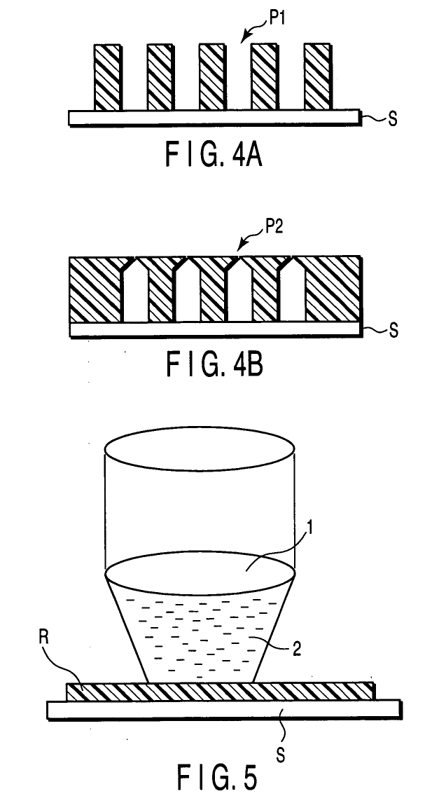

FIGS. 4A, 4B show resist pattern shapes. By using the resist protective film as described above, a resist pattern P1 of a good shape is obtained as shown in FIG. 4A. On the other hand, when the resist protective film is not used, as shown in FIG. 4B, a resist pattern P2 exhibits a T-top shape which is not good.

FIG. 5 is a view showing an apparatus configuration in which a method for forming a resist pattern according to a second embodiment is implemented. As shown in FIG. 5, a silicon substrate S is arranged below an objective lens 1 disposed in a liquid immersion type exposing apparatus. A space between the objective lens 1 and the silicon substrate S is filled with a liquid (pure water) 2. As described later, a resist film R is formed on the silicon substrate S, and a surface of the resist film R becomes hydrophilic.

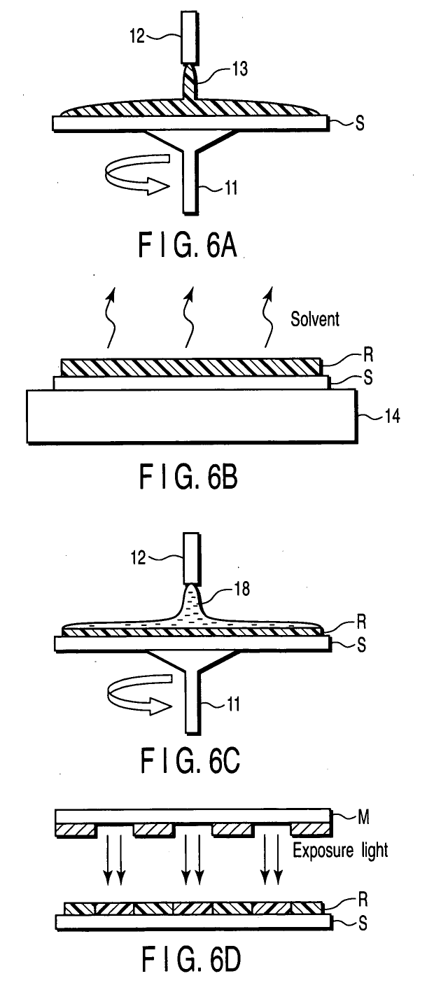

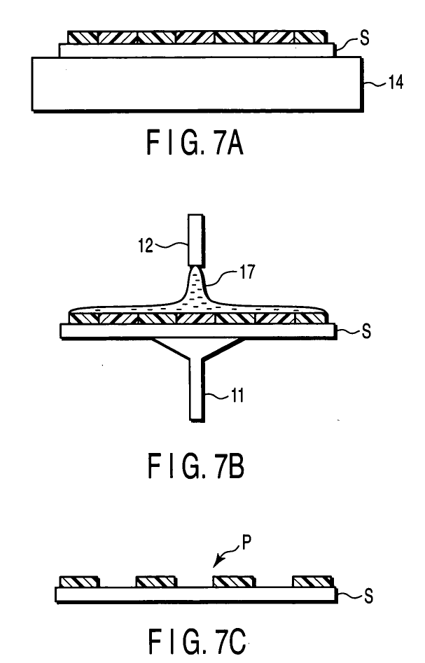

FIGS. 6A to 6D and FIGS. 7A to 7C are views showing a process flow of the method for forming the resist pattern according to the second embodiment. Hereinafter, the process of the resist pattern formation will be described with reference to FIGS. 6A to 6D and FIGS. 7A to 7C.

First, a reflection preventing film solution (ARC29A by Nissan Chemical Co. Ltd.) is applied on the silicon substrate S, baked on a hot plate at 190° C. for 60 sec., and a reflection preventing film (film to be processed) of a thickness of 80 nm is obtained.

Subsequently, as shown in FIG. 6A, a lower layer resist solution 13 is supplied through a nozzle 12 to the silicon substrate S while the silicon substrate S is rotated by a spin chuck 11. Accordingly, a methacrylate ArF chemically amplified positive resist (film thickness of 300 nm) is applied on the reflection preventing film. Next, as shown in FIG. 6B, the silicon substrate S is baked on the hot plate 14 at 120° C. for 60 sec., and a resist film R is formed on the silicon substrate S.

Then, as shown in FIG. 6C, ozone water 18 is supplied through the nozzle 12 to the resist film R of the silicon substrate S while the silicon substrate S is rotated by the spin chuck 11. Accordingly, when the resist film R is immersed in ozone water of 5 ppm supplied from an ozone water supply device, the surface of the resist film R with which the liquid 2 is brought into contact becomes hydrophilic, and a contact angle of the pure water is reduced from 65° to 55°.

Next, as shown in FIG. 6D, in a liquid immersion type ArF excimer laser exposing apparatus that uses water as a medium, a line-and-space pattern of a line width 100 nm is transferred through the objective lens 1 to the silicon substrate S by using a half-tone mask M of a transmittance 6% under conditions of NA=0.68, σ=0.75, and 2/3 orbicular zone illumination. Then, as shown in FIG. 7A, PEB treatment is executed on the hot plate 14 of 120° C. for 60 sec.

Next, as shown in FIG. 7B, a developing liquid 17 is supplied through the nozzle 12 to the silicon substrate S. Accordingly, the silicon substrate S is immersed in the developing liquid which contains a 2.38 wt % TMAH aqueous solution for 30 sec., and developing is carried out.

As a result, as shown in FIG. 7C, a resist pattern P of a good shape is obtained.

Incidentally, by immersing the resist film R in a 1% sulfuric acid aqueous solution in place of the ozone water for 60 sec., the contact angle can be reduced from 65° to 35°.

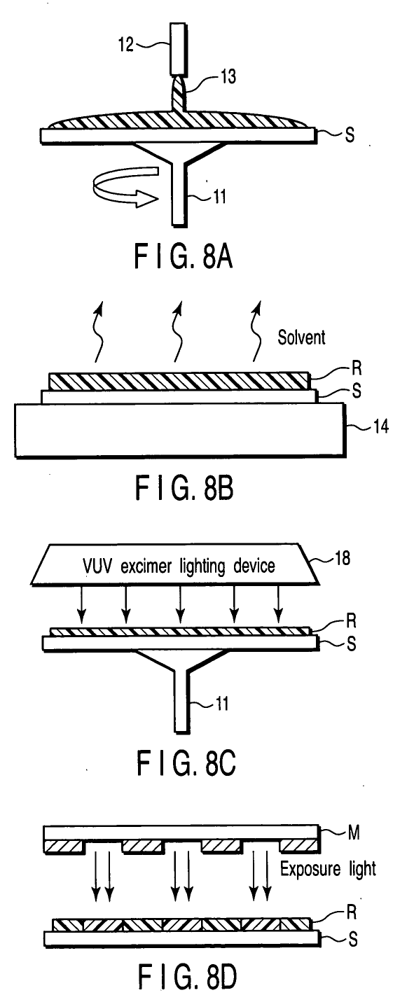

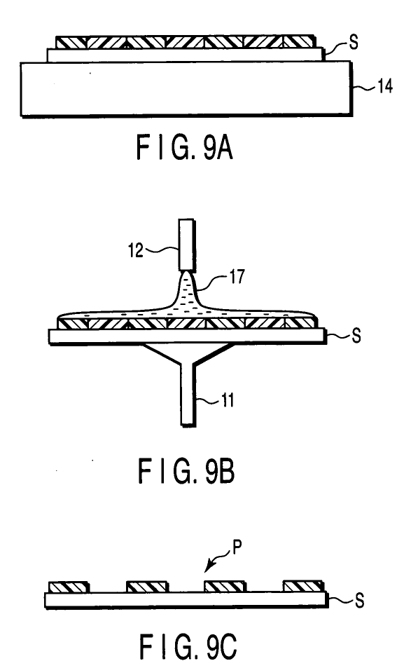

FIGS. 8A to 8D and FIGS. 9A to 9C are views showing a process flow of a method for forming a resist pattern according to a third embodiment. Hereinafter, the process of the resist pattern formation will be described with reference to FIGS. 8A to 8D and FIGS. 9A to 9C.

First, as in the case of the second embodiment, as shown in FIGS. 8A, 8B, a resist film R is formed on a silicon substrate S. Subsequently, as shown in FIG. 8C, the resist film R is irradiated with an excimer light by a VUV excimer lighting device 18 of 172 nm at a room temperature in the atmosphere for 10 sec. Irradiance is 5 mW/cm², and a gap between a lamp and the silicon substrate S is 2 mm. Accordingly, a contact angle of the pure water with a surface of the resist film R is reduced from 65° to 35°.

Next, as shown in FIG. 8D, in a liquid immersion type ArF excimer laser exposing apparatus that uses water as a medium, a line-and-space pattern of a line width 100 nm is transferred through an objective lens 1 to the silicon substrate S by using a half-tone mask M of a transmittance 6% under conditions of NA=0.68, σ=0.75, and 2/3 orbicular zone illumination. Then, as shown in FIG. 9A, PEB treatment is executed on a hot plate 14 of 120° C. for 60 sec.

Next, as shown in FIG. 9B, a developing liquid 17 is supplied through a nozzle 12 to the silicon substrate S. Accordingly, the silicon substrate S is immersed in the developing liquid which contains a 2.38 wt % TMAH aqueous solution for 30 sec., and developing is carried out.

As a result, as shown in FIG. 9C, a resist pattern P of a good shape is obtained.

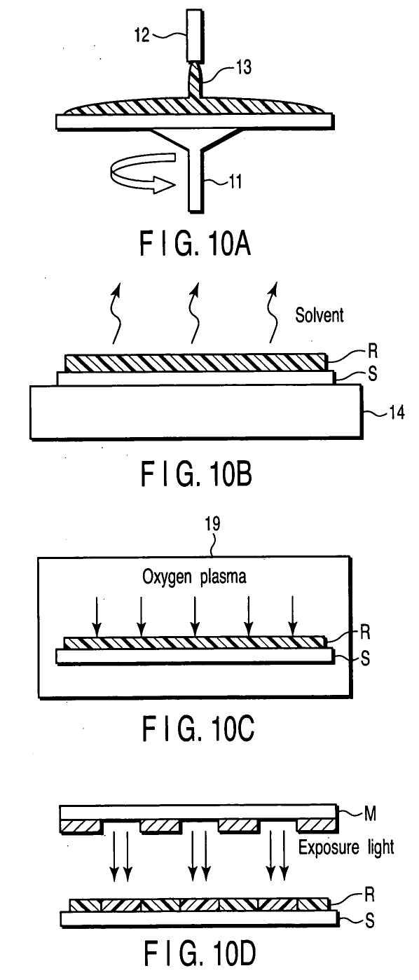

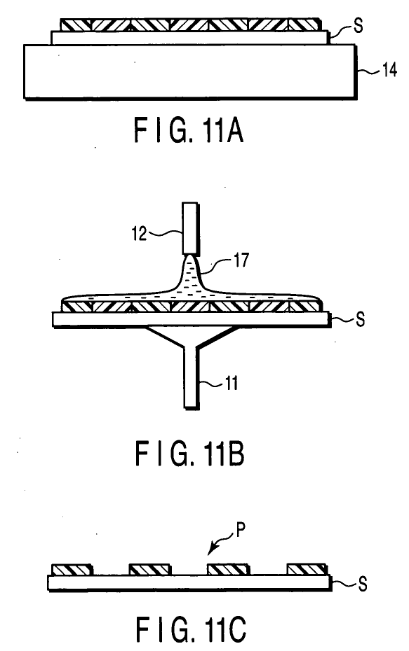

FIGS. 10A to 10D and FIGS. 11A to 11C are views showing a process flow of a method for forming a resist pattern according to a fourth embodiment. Hereinafter, the process of the resist pattern formation will be described with reference to FIGS. 10A to 10D and FIGS. 11A to 11C.

First, as in the case of the second embodiment, as shown in FIGS. 10A, 10B, a resist film R is formed on a silicon substrate S. Subsequently, as shown in FIG. 10C, the silicon substrate S is placed in a vacuum chamber 19, and subjected to plasma treatment in an oxygen atmosphere. Accordingly, a contact angle of pure water with a surface of the resist film R is reduced from 65° to 30°.

Next, as shown in FIG. 10D, in a liquid immersion type ArF excimer laser exposing apparatus that uses water as a medium, a line-and-space pattern of a line width 100 nm is transferred through an objective lens 1 to the silicon substrate S by using a half-tone mask M of a transmittance 6% under conditions of NA=0.68, σ=0.75, and 2/3 orbicular zone illumination. Then, as shown in FIG. 11A, PEB treatment is executed on a hot plate 14 of 120° C. for 60 sec.

Next, as shown in FIG. 11B, a developing liquid 17 is supplied through a nozzle 12 to the silicon substrate S. Accordingly, the silicon substrate S is immersed in the developing liquid which contains a 2.38 wt % TMAH aqueous solution for 30 sec., and developing is carried out.

As a result, as shown in FIG. 11C, a resist pattern P of a good shape is obtained.

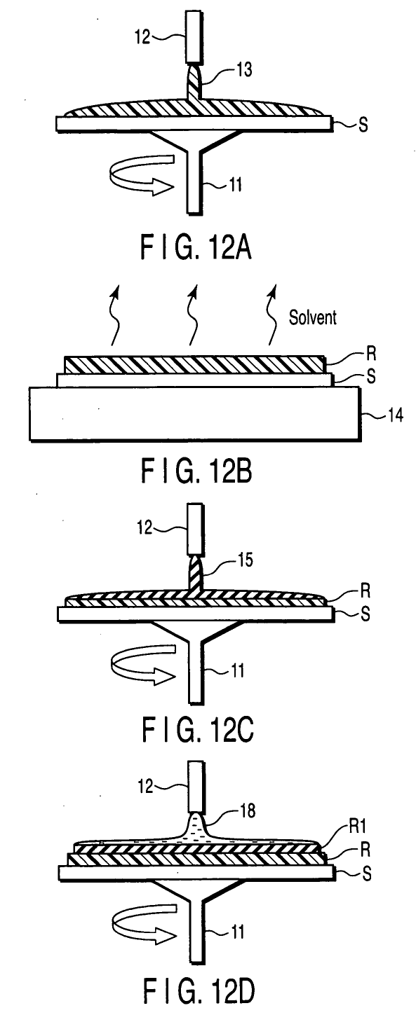

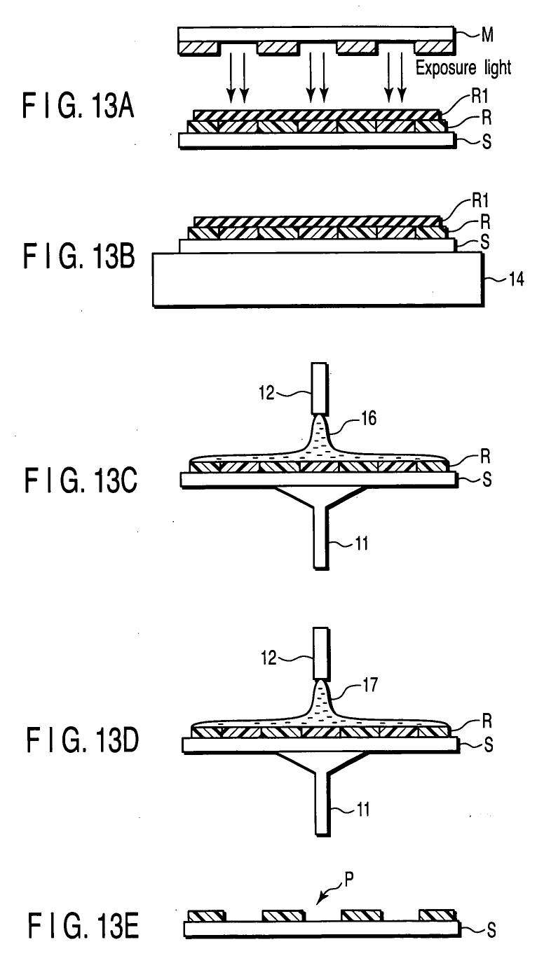

FIGS. 12A to 12D and FIGS. 13A to 13E are views showing a process flow of a method for forming a resist pattern according to a fifth embodiment. Hereinafter, the process of the resist pattern formation will be described with reference to FIGS. 12A to 12D and FIGS. 13A to 13E.

First, a reflection preventing film solution (ARC29A by Nissan Chemical Co. Ltd.) is applied on a silicon substrate S, baked on a hot plate at 190° C. for 60 sec., and a reflection preventing film (film to be processed) of a thickness of 80 nm is obtained.

Subsequently, as shown in FIG. 12A, a lower layer resist solution 13 is supplied through a nozzle 12 to the silicon substrate S while the silicon substrate S is rotated by a spin chuck 11. Accordingly, a methacrylate ArF chemically amplified positive resist (film thickness of 300 nm) is applied on the reflection preventing film. Next, as shown in FIG. 12B, the silicon substrate S is baked on the hot plate 14 at 120° C. for 60 sec., and a resist film R is formed on the silicon substrate S.

Then, as shown in FIG. 12C, a protective film aqueous solution 15 is supplied through the nozzle 12 to the resist film R of the silicon substrate S while the silicon substrate S is rotated by the spin chuck 11. Accordingly, a polysilsesquioxane aqueous solution of a solid portion concentration 6 wt % is applied with a film thickness of 60 nm on the resist film R. Subsequently, heat treatment is executed on the hot plate of 120° C. for 60 sec., and insoluble treatment is executed. Thus, a resist protective film R1 that becomes insoluble in a liquid 2 is formed on a surface of the resist film R.

Next, as shown in FIG. 12D, ozone water 18 is supplied through the nozzle 12 to the resist film R of the silicon substrate S while the silicon substrate S is rotated by the spin chuck 11. Accordingly, when the resist film R is immersed in ozone water of 5 ppm supplied from an ozone water supply device for 5 min., a surface of the resist protective film R1 with which the liquid 2 is brought into contact becomes hydrophilic, and a contact angle of pure water is reduced from 55° to 45°.

Next, as shown in FIG. 13A, in a liquid immersion type ArF excimer laser exposing apparatus that uses water as a medium, a line-and-space pattern of a line width 100 nm is transferred through an objective lens 1 to the silicon substrate S by using a half-tone mask M of a transmittance 6% under conditions of NA=0.68, σ=0.75, and 2/3 orbicular zone illumination. Then, as shown in FIG. 13B, PEB treatment is executed on the hot plate 14 of 120° C. for 60 sec.

Next, as shown in FIG. 13C, a peeling liquid 16 is supplied through the nozzle 12 to the silicon substrate S. Accordingly, the silicon substrate S is immersed in a 0.1% hydrofluoric acid solution for 30 sec., and the polysilsesquioxane film, i.e., the resist protective film R1, is removed. Then, as shown in FIG. 13D, a developing liquid 17 is supplied through the nozzle 12 to the silicon substrate S. Thus, the silicon substrate S is immersed in the developing liquid which contains a 2.38 wt % TMAH aqueous solution for 30 sec., and developing is carried out.

As a result, as shown in FIG. 13E, a resist pattern P of a good shape is obtained.

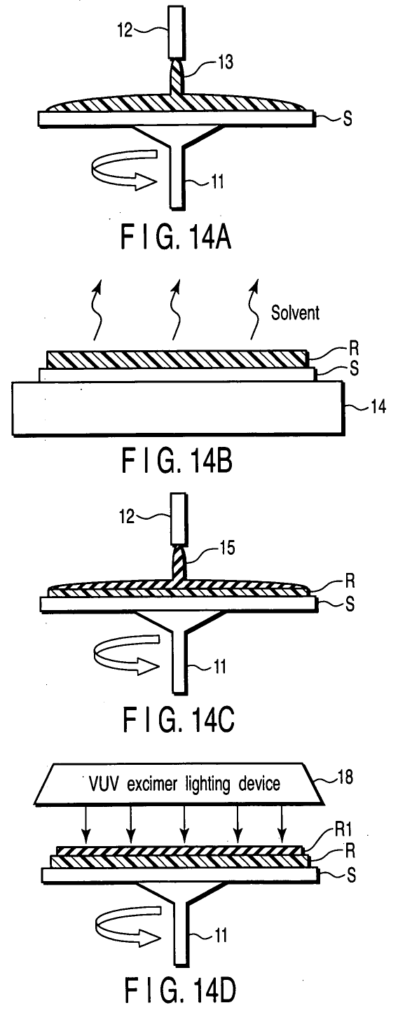

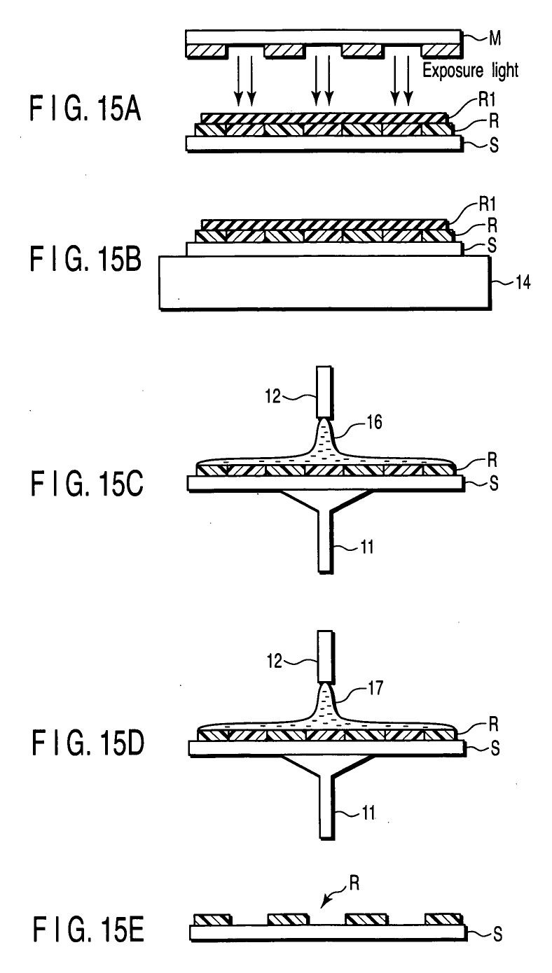

FIGS. 14A to 14D and FIGS. 15A to 15E are views showing a process flow of a method for forming a resist pattern according to a sixth embodiment. Hereinafter, the process of the resist pattern formation will be described with reference to FIGS. 14A to 14D and FIGS. 15A to 15E.

First, a reflection preventing film solution (ARC29A by Nissan Chemical Co. Ltd.) is applied on a silicon substrate S, baked on a hot plate at 190° C. for 60 sec., and a reflection preventing film (film to be processed) of a thickness of 80 nm is obtained. Subsequently, as shown in FIG. 14A, a lower layer resist solution 13 is supplied through a nozzle 12 to the silicon substrate S while the silicon substrate S is rotated by a spin chuck 11. Accordingly, a methacrylate ArF chemically amplified positive resist (film thickness of 300 nm) is applied on the reflection preventing film.

Next, as shown in FIG. 14B, the silicon substrate S is baked on a hot plate 14 at 120° C. for 60 sec., and a resist film R is formed on the silicon substrate S. Then, as shown in FIG. 14C, a protective film aqueous solution 15 is supplied through the nozzle 12 to the resist film R of the silicon substrate S while the silicon substrate S is rotated by the spin chuck 11. Accordingly, a polysilsesquioxane aqueous solution of a solid portion concentration 6 wt % is applied with a film thickness of 60 nm on the resist film R. Subsequently, heat treatment is executed on the hot plate of 120° C. for 60 sec., and insoluble treatment is executed. Thus, a resist protective film R1 that becomes insoluble in a liquid 2 is formed on a surface of the resist film R.

Next, as shown in FIG. 14D, the resist film R is irradiated with an excimer light by a VUV excimer lighting device 18 of 172 nm at a room temperature in an atmosphere for 10 sec. Irradiance is 5 mW/cm², and a gap between a lamp and the silicon substrate S is 2 mm. Accordingly, a contact angle of pure water with a surface of the resist film R is reduced from 65° to 35°.

Next, as shown in FIG. 15A, in a liquid immersion type ArF excimer laser exposing apparatus that uses water as a medium, a line-and-space pattern of a line width 100 nm is transferred through an objective lens 1 to the silicon substrate S by using a half-tone mask M of a transmittance 6% under conditions of NA=0.68, σ=0.75, and 2/3 orbicular zone illumination. Then, as shown in FIG. 15B, PEB treatment is executed on the hot plate 14 of 120° C. for 60 sec.

Next, as shown in FIG. 15C, a peeling liquid 16 is supplied through the nozzle 12 to the silicon substrate S. Accordingly, the silicon substrate S is immersed in a 0.1% hydrofluoric acid solution for 30 sec., and the polysilsesquioxane film, i.e., the resist protective film R1, is removed. Then, as shown in FIG. 15D, a developing liquid 17 is supplied through the nozzle 12 to the silicon substrate S. Thus, the silicon substrate S is immersed in the developing liquid which contains a 2.38 wt % TMAH aqueous solution for 30 sec., and developing is carried out.

As a result, as shown in FIG. 15E, a resist pattern P of a good shape is obtained.

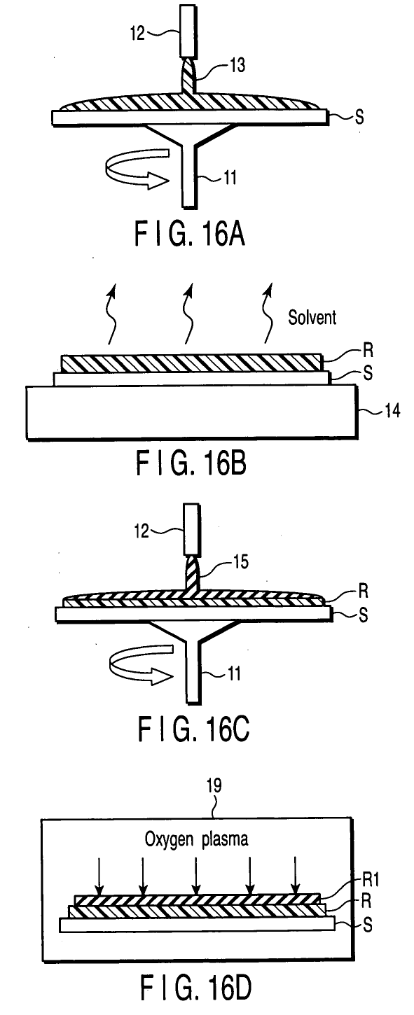

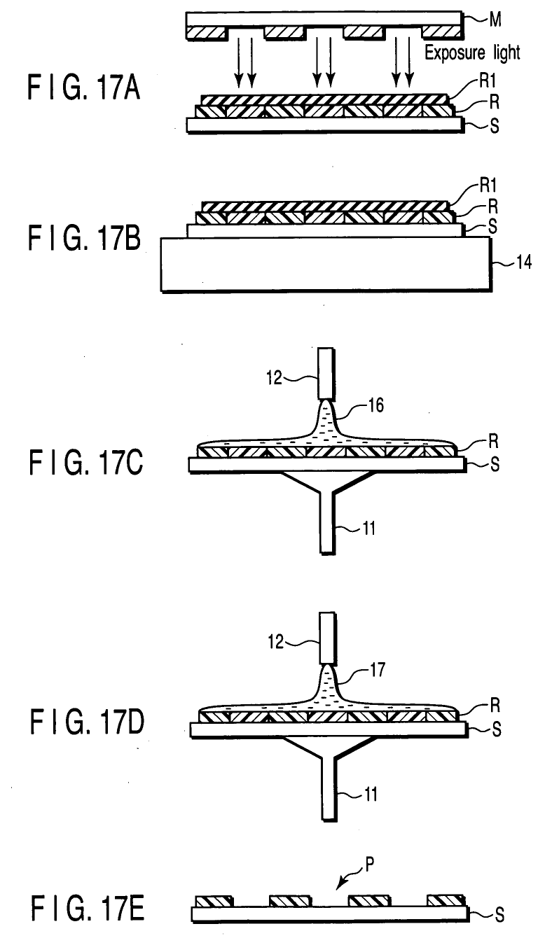

FIGS. 16A to 16D and FIGS. 17A to 17E are views showing a process flow of a method for forming a resist pattern according to a seventh embodiment. Hereinafter, the process of the resist pattern formation will be described with reference to FIGS. 16A to 16D and FIGS. 17A to 17E.

First, a reflection preventing film solution (ARC29A by Nissan Chemical Co. Ltd.) is applied on a silicon substrate S, baked on a hot plate at 190° C. for 60 sec., and a reflection preventing film (film to be processed) of a thickness of 80 nm is obtained.

Subsequently, as shown in FIG. 16A, a lower layer resist solution 13 is supplied through a nozzle 12 to the silicon substrate S while the silicon substrate S is rotated by a spin chuck 11. Accordingly, a methacrylate ArF chemically amplified positive resist (film thickness of 300 nm) is applied on the reflection preventing film. Next, as shown in FIG. 16B, the silicon substrate S is baked on the hot plate 14 at 120° C. for 60 sec., and a resist film R is formed on the silicon substrate S.

Then, as shown in FIG. 16C, a protective film aqueous solution 15 is supplied through the nozzle 12 to the resist film R of the silicon substrate S while the silicon substrate S is rotated by the spin chuck 11. Accordingly, a polysilsesquioxane aqueous solution of a solid portion concentration 6 wt % is applied with a film thickness of 60 nm on the resist film R. Subsequently, heat treatment is executed on the hot plate of 120° C. for 60 sec., and insoluble treatment is executed. Thus, a resist protective film R1 that becomes insoluble in a liquid 2 is formed on a surface of the resist film R.

Next, as shown in FIG. 16D, the silicon substrate S is placed in a vacuum chamber 19, and subjected to plasma treatment in an oxygen atmosphere. Thus, a contact angle of pure water with a surface of the resist film R is reduced from 550 to 250.

Next, as shown in FIG. 17A, in a liquid immersion type ArF excimer laser exposing apparatus that uses water as a medium, a line-and-space pattern of a line width 100 nm is transferred through an objective lens 1 to the silicon substrate S by using a half-tone mask M of a transmittance 6% under conditions of NA=0.68, σ=0.75, and 2/3 orbicular zone illumination. Then, as shown in FIG. 17B, PEB treatment is executed on the hot plate 14 of 120° C. for 60 sec.

Next, as shown in FIG. 17C, a peeling liquid 16 is supplied through the nozzle 12 to the silicon substrate S. Accordingly, the silicon substrate S is immersed in a 0.1% hydrofluoric acid solution for 30 sec., and the polysilsesquioxane film, i.e., the resist protective film R1, is removed. Then, as shown in FIG. 17D, a developing liquid 17 is supplied through the nozzle 12 to the silicon substrate S. Thus, the silicon substrate S is immersed in the developing liquid which contains a 2.38 wt % TMAH aqueous solution for 30 sec., and developing is carried out.

As a result, as shown in FIG. 17E, a resist pattern P of a good shape is obtained.

According to the embodiment, the formation of the resist pattern in the lithography process in the manufacturing of the semiconductor device includes a step of directly or indirectly forming a resist film on a semiconductor substrate in which a processed film is formed, a step of exposing the resist film by a liquid immersion type exposing apparatus which executes exposure in a state in which a space between the semiconductor device and an objective lens is filled with liquid, and a step of developing the resist film. The formation of the resist pattern further includes a step of forming a resist protective film made of a soluble inorganic material on the resist film after the formation of the resist film and before the exposure thereof, a step of making insoluble the resist protective film in the liquid used in the liquid immersion type exposing apparatus, and a step of removing the resist protective film after the exposure of the resist film and before the development thereof.

As a material of the resist protective film, a soluble inorganic film (spin on glass: SOG) material or the like is preferred.

In the step of making insoluble the resist protective film in the liquid used in the liquid immersion type exposing apparatus, a method for subjecting the resist protective film to heat treatment, a method for irradiating the resist protective film with an ultraviolet light (UV irradiation), a method for applying an electron beam (EB irradiation), or a combination thereof is preferably employed.

As the method for removing the resist protective film, a method for using an organic solvent in which a resist material is insoluble, a hydrofluoric acid aqueous solution, an oxidative aqueous solution such as an ammonium fluoride aqueous solution, an alkali aqueous solution such as tetramethylammonium hydroxide aqueous solution, or a combination thereof is preferably employed before the developing step of the resist film.

Additionally, according to the embodiment, the resist film formed on the semiconductor substrate in which the film to be processed is formed is subjected to exposure by using the liquid immersion type exposing apparatus. Further, a surface of the semiconductor substrate with which the liquid used in the immersion type exposing apparatus is brought into contact is hydrophilic to the liquid.

As described above, since the surface of the semiconductor substrate with which the liquid used in the immersion type exposing apparatus is directly brought into contact is hydrophilic to the liquid, it is possible to suppress sticking of bubbles to the surface of the substrate which distorts an optical image on the resist in the exposure to deteriorate the resist pattern.

In the step of making the surface of the semiconductor substrate hydrophilic to the liquid, a method for executing heat treatment in an atmosphere containing oxygen, a method for applying an ultraviolet light (UV irradiation), a method for applying an electron beam (EB irradiation), or a method for combining a plurality thereof is preferably used.

When the liquid is water, if the surface of the semiconductor substrate which directly comes into contact with the liquid is a resist film surface, a resist solution is applied on the semiconductor substrate, the surface of the resist film is immersed into an oxidative aqueous solution or exposed to an oxidative atmosphere after the formation of the resist film. Accordingly, the surface of the resist film is oxidized to make the surface of the semiconductor substrate hydrophilic.

Here, as the oxidative aqueous solution, an aqueous solution containing one or more kinds of acids such as hydrogen peroxide, a hydrochloric acid, a sulfuric acid, and a hydrofluoric acid, or an aqueous solution containing ozone is preferably used. Regarding acidity of the oxidative aqueous solution, the acidity is preferably optimized for the resist. That is, it is because no sufficient bubble removing effect is obtained if an oxidizing force is weak, and the resist film is dissolved in the developing liquid or the water to make the pattern formation difficult if an oxidizing force is too strong.

On the other hand, as the oxidative atmosphere, a method for exposure to a plasma containing oxygen, a method for exposure to an atmosphere containing ozone or the like is conceivable. As an ozone generation method, a method for applying a UV light in the atmosphere containing oxygen or the like can be cited. Additionally, heating treatment may be executed in the atmosphere containing oxygen.

According to the embodiment of the present invention, when the liquid immersion type exposing apparatus is used, it is possible to provide a resist pattern forming method which can form an always stable resist pattern, and a method for manufacturing a semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A method for forming a resist pattern by using a liquid immersion type exposing apparatus which executes exposure in a state in which a space between a resist film and an objective lens is filled with a liquid, comprising:
forming a film to be processed on a substrate to be processed;
forming the resist film on the substrate to be processed on which the film to be processed is formed;
forming a resist protective film on the resist film; and
exposing the resist film after the formation of the resist protective film.

2. The method according to claim 1, wherein the resist protective film includes inorganic contents.

3. The method according to claim 1, wherein the formation of the resist protective film includes insolubilization of the resist protective film in the liquid.

4. The method according to claim 3, wherein in the insolubilization, the resist protective film is subjected to heat treatment.

5. The method according to claim 3, wherein in the insolubilization, the resist protective film is irradiated with an ultraviolet light or an electron beam.

6. The method according to claim 1, further comprising removing the resist protective film after the exposure of the resist film and before the development thereof.

7. A method for forming a resist pattern by using a liquid immersion type exposing apparatus which executes exposure in a state in which a space between a resist film and an objective lens is filled with a liquid, comprising:
forming a film to be processed on a processed substrate;
forming the resist film on the substrate to be processed on which the film to be processed is formed;
making hydrophilic a surface of the resist film with which the liquid is brought into contact; and
exposing the resist film after the surface thereof is made hydrophilic.

8. The method according to claim 7, wherein in the making-hydrophilic of the surface of the resist film, the surface of the resist film is immersed in an oxidative solution.

9. The method according to claim 7, wherein in the making-hydrophilic of the surface of the resist film, the surface of the resist film is exposed to an oxidative atmosphere.

10. A method for forming a resist pattern by using a liquid immersion type exposing apparatus which executes exposure in a state in which a space between a resist film and an objective lens is filled with a liquid, comprising:
forming a film to be processed on a substrate to be processed;
forming the resist film on the substrate to be processed on which the film to be processed is formed;
forming a resist protective film on the resist film;
making hydrophilic a surface of the resist protective film with which the liquid is brought into contact; and
exposing the resist film after the surface of the resist protective film is made hydrophilic.

11. The method according to claim 10, wherein the resist protective film includes inorganic contents.

12. The method according to claim 10, wherein the formation of the resist protective film includes insolubilization of the resist protective film in the liquid.

13. The method according to claim 12, wherein in the insolubilization, the resist protective film is subjected to heat treatment.

14. The method according to claim 12, wherein in the insolubilization, the resist protective film is irradiated with an ultraviolet light or an electron beam.

15. The method according to claim 10, further comprising removing the resist protective film after the exposure of the resist film and before the development thereof.

16. The method according to claim 10, wherein in the making-hydrophilic of the surface of the resist protective film, the surface is immersed in an oxidative solution.

17. The method according to claim 10, wherein in the making-hydrophilic of the surface of the resist protective film, the surface is exposed to an oxidative atmosphere.

18. A method for manufacturing a semiconductor device by using a liquid immersion type exposing apparatus which executes exposure in a state in which a space between a resist film and an objective lens is filled with a liquid, comprising:
forming a film to be processed on a semiconductor substrate;
forming the resist film on the semiconductor substrate on which the film to be processed is formed;
forming a resist protective film which becomes insoluble in the liquid on the resist film; and
exposing the resist film after the formation of the resist protective film.

19. A method for manufacturing a semiconductor device by using a liquid immersion type exposing apparatus which executes exposure in a state in which a space between a resist film and an objective lens is filled with a liquid, comprising:
forming a film to be processed on a semiconductor substrate;
forming the resist film on the semiconductor substrate on which the film to be processed is formed;
making hydrophilic a surface of the resist film with which the liquid is brought into contact; and
exposing the resist film after the surface thereof is made hydrophilic.

20. A method for manufacturing a semiconductor device by using a liquid immersion type exposing apparatus which executes exposure in a state in which a space between a resist film and an objective lens is filled with a liquid, comprising:
forming a film to be processed on a semiconductor substrate;
forming the resist film on the semiconductor substrate on which the film to be processed is formed;
forming a resist protective film on the resist film;
making hydrophilic a surface of the resist protective film with which the liquid is brought into contact; and
exposing the resist film after the surface of the resist protective film is made hydrophilic.
